(19) United States
(12) Patent Application Publication
(10) Pub. No.: US 2009/0146194 A1
(43) Pub. Date: Jun. 11, 2009

(54) SEMICONDUCTOR DEVICE AND METHOD OF MANUFACTURING A SEMICONDUCTOR DEVICE

(75) Inventors: Kirsten MOSELUND, Zurich (CH); Mihai Adrian Ionescu, Ecublens VD (CH); Didier Bouvet, Morges (CH)

Correspondence Address: NIXON & VANDERHYE, PC, 901 NORTH GLEBE ROAD, 11TH FLOOR, ARLINGTON, VA, 22203, US

(73) Assignee: ECOLE POLYTECHNIQUE FEDERALE DE LAUSANNE (EPFL), Lausanne (CH)

(21) Appl. No.: 12/328,998

(22) Filed: Dec. 5, 2008

Related U.S. Application Data
(60) Provisional application No. 60/992,401, filed on Dec. 5, 2007.

(51) Int. Cl. H01L 29/78; H01L 21/336; H01L 29/66

(52) U.S. Cl. 257/288; 438/197; 257/E29.168; 257/E29.255; 257/E21.409; 977/766; 977/938

(57) ABSTRACT

The local bending of a silicon nanowire induces tensile strain in the wire due to the stretching of the silicon lattice. This in turn enhances the mobility of the free carriers (electrons) in the direction of transport along the wire. Thus, for example, when Gate-All-Around MOSFETs are fabricated along the nanowire, the mobility enhancement will translate into an improvement in the performance (current drive, speed) of the silicon nanowire MOSFETs. In summary, a semiconductor device comprises a substrate and a nanowire in connection with the substrate at a drain and at a source region, and the nanowire is bent to achieve enhanced mobility of charge carriers.

### SUMMARY OF THE INVENTION

The present invention describes bending of nanowires.

A local bending of a silicon nanowire induces tensile strain in the wire, due to the stretching of the silicon lattice. This in turn enhances the mobility of the free carriers (electrons) in the direction of transport along the wire. Thus, for example when Gate-All-Around MOSFETs are fabricated along said nanowire, the mobility enhancement will translate into an improvement in the performance (current drive, speed) of the silicon nanowire MOSFETs.

### BACKGROUND OF THE INVENTION

### Field of the Invention

The present invention relates a semiconductor device and its manufacturing, and particularly to high performance transistors for integrated circuits exploiting strained device regions to enhance charge carrier mobility in the channel region of a MOS transistor. More particularly, it refers to multi-gate nanowire MOS transistors that exploit the strain related to local oxidation induced bending of nanowire structures and the method to achieve it. Strain in silicon MOSFETs is known to increase carrier mobility [1-3]. A new device concept—the bended transistor architecture—and a method to achieve it are proposed in contrast with existing strain technologies that are based on using strain-inducing material.

The field of the invention is extendable to high performance nanowire sensors and nano-electro-mechanical resonators.

### State-of-the-art

The fabrication of integrated circuits is currently based on the formation of a very large number of circuit elements on a given wafer area according to a designed circuit layout. A diversity of process technologies are exploited to realize such complex integrated circuits, such as microprocessors, storage chips and the like, silicon CMOS technology is currently one of the most promising approaches, due to the superior characteristics in view of operating speed and/or power consumption and/or cost efficiency.

The fabrication of complex integrated circuits using CMOS technology involves the formation of millions of transistors, i.e., N-channel and P-channel MOS transistors, on a substrate including a crystalline semiconductor layer.

The conductivity of the channel region, depends on various parameters such as the dopant concentration, the mobility of the majority charge carriers, and on the dimensions of the channel region, which are also referred to as channel length and width. The overall conductivity of the channel region substantially determines the performance of the MOS transistors. In addition, the conductivity of the channel region and, consequently, the drive current capability of the MOSFET, is also modulated by an electrical field induced by a capacitive gate stack

Traditionally, the reduction of the channel length was the primary means for obtaining an increase in the operating speed of the integrated circuits. The continuing reduction of the transistor dimensions, however, involves many issues associated therewith, such as short channel effects that have to be addressed so as to not unduly offset the advantages obtained by steadily decreasing the channel length of MOS transistors. Since the continuous size reduction of the critical dimensions, i.e., the gate length of the transistors, necessitates new development of highly complex process techniques, for example, for compensating for short channel effects, it has been proposed to also enhance the channel conductivity of the transistor elements by increasing the charge carrier mobility in the channel region for a given channel length. On the other hand the better control of short channel effect can be achieved by using thin film multi-gate devices or nanowire transistors. These solutions offer the potential for achieving a performance improvement needed for advanced CMOS technology nodes.

An efficient method for increasing the charge carrier mobility is the modification of the lattice structure in the channel region, for instance by creating tensile or compressive stress in the vicinity of the channel region, which can result in increased mobility for electrons and holes, respectively, see for example [3]. For example, tensile strain in the channel region may increase the mobility of electrons, thereby providing the potential for enhancing the performance of N-type transistors, whereas compressive stress is known to enhance the mobility of holes [3].

The introduction of stress or strain engineering into integrated circuit fabrication is an extremely promising approach for future CMOS generations and strained silicon material acts as a material with new conduction properties, related to the applied strain, which enable the fabrication of better semiconductor devices, thus this may prolong the reign of silicon based electronics without having to resort to expensive new semiconductor materials such as III-Vs.

Some common proposed methods for introducing strain in MOSFET technologies include:
i) the use of substrate incorporating SiGe layers whereby the silicon channel region can be strained. The disadvantage of this approach is the obvious need for a much more costly substrate, and in addition strain is not introduced locally, but on the full wafer level [4-5].
ii) in order to enhance the hole mobility of a PMOS transistors the source and drain regions can be formed by silicon/germanium, wherein a compressive strain is created in the adjacent silicon channel region. Similar concepts have been proposed for N-channel transistors by using a silicon/carbon material that has a smaller lattice spacing compared to silicon. Although it should be possible to do this optimization locally, it still requires costly non-standard processing such as epitaxy to create the SiGe regions [6-7].
iii) the use of nitride caps and/or a combination of various stressor materials surrounding the transistor gate and channel.

These approaches differ in complication and efficiency [8-9]. Furthermore, in [2] it was found that the mobility enhancement due to strain is much more pronounced in silicon nanowires compared to planar devices. In silicon nanowires the proper strain can cause a doubling of the carrier mobility, whereas in planar devices, the performance gain is generally in the range of 5-15%. However, in that case the strain was induced by a bending of the entire wafer/die, which is obviously not appropriate for fabrication.

### DETAILED DESCRIPTION OF THE INVENTION

The present invention describes bending of silicon nanowires by oxidation as a method to introduce local strain in nanowire devices. A local bending of a silicon nanowire induces tensile strain in the wire, due to the stretching of the silicon lattice. This in turn enhances the mobility of the free carriers (electrons) in the direction of transport along the wire.

Thus, when for example Gate-All-Around MOSFETs are fabricated along the said nanowire, the mobility enhancement will translate into an improvement in the performance (current drive, speed) of the silicon nanowire MOSFETs.

The present invention is directed towards a completely new approach, i.e bending the transistor body itself during fabrication in order to achieve the needed strain for carrier mobility enhancement. The bending is caused by a sacrificial oxidation steps, and hence it does not require advanced processing and/or new materials placed in the channel vicinity in order to induce the necessary strain. Oxidation is also a very well controlled process used extensively in usual CMOS fabrication, thus oxidation-induced bending does not require the introduction of new equipment or know-how into the fabrication line. A new device architecture, a bended transistor, and method to achieve it for scaled MOSFET architectures showing the best control of short channel effects, the multi-gate nanowire transistor, are proposed.

Bended devices can find suitable applications beyond the MOSFET electronic switch and cover many other fields as high performance advanced sensors or Nano-Electro-Mechanical (NEM) devices.

Even though, oxidation is a well established fabrication technology, some fine tuning depending on the exact design will be required in order to obtain the desired amount of strain in a given device. Especially, since for nanoscale structures oxidation speeds are strain dependent. The latter fact is exploited today to obtain ultra small structures using the pattern-dependent oxidation (PADOX) process [10] on Silicon-On-Insulator substrates; therefore this is not considered an obstacle for the current invention.

A further advantage of the present method is that strain is only introduced in the bended MOSFET channel, and not in the source and drain regions, thereby preserving low leakage current, as there is no reduction of the bandgap (as in other previously proposed strained and SiGe solutions) in the source and drain regions.

A top-down approach can be used to locally fabricate bended silicon devices on a silicon wafer, thereby allowing a monolithic integration with CMOS.

The present invention does not pertain to the wire fabrication itself, but describes a method for bending suspended silicon nanowires, hereby inducing tensile strain, which is compatible with conventional CMOS processing technologies and does not require the introduction of materials other than silicon.

Previously described bending principles also apply to membrane silicon devices.

By bending of the nanowires rather than the wafer/die it is possible to introduce tensile strain locally in devices. When a nanowire is oxidized, the created oxide has a greater volume than the consumed silicon, thus it will induce strain in the suspended structure. The stress from the oxide is accommodated by a stretching of the silicon lattice, i.e. bending of the wire. When the bending is important it remains even when the oxide is removed from the wire, see e.g. FIG. 2 a. This introduces a tensile stress in the wire. Tensile strain in silicon is known to increase electron mobility for current transport. When a gate-all-around MOSFET is fabricated on the bended wire, this can be measured as a significant increase of the drain current of the device due to the increase of the carrier (electron) mobility. The exact level of the tensile strain can be experimentally revealed using a micro-Raman measurement [12].

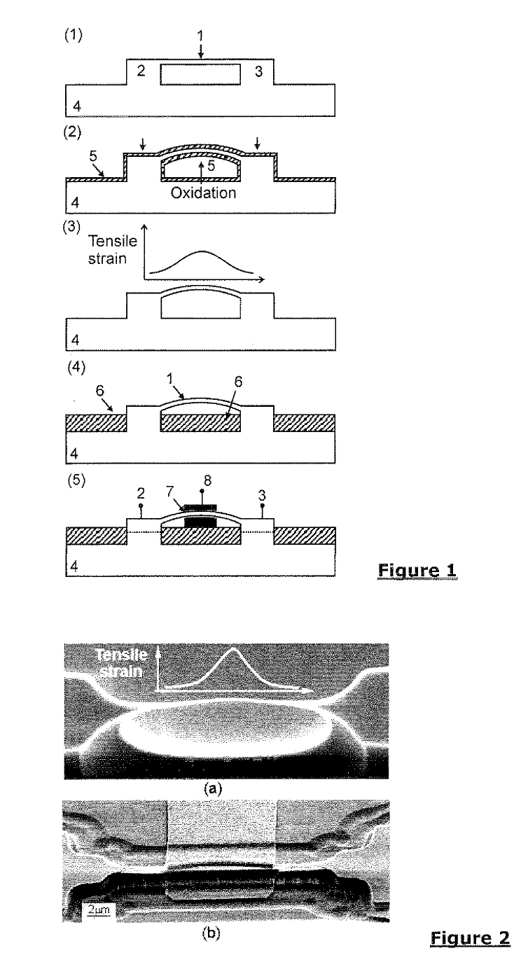

In the following description of the fabrication method we refer to the steps indicated in FIG. 1 which describes a method of oxidation induced bending and tensile strain in silicon nanowires according to a preferred embodiment of the invention.

In FIG. 1 at step (1), the starting point, a silicon nanowire is connected at the two ends to the source and drain plots, In step (2) it is shown how oxidation induces bending in the nanowire due the change in volume combined with the mechanical clamping of the nanowires at both ends.

Even when the oxide is removed the silicon lattice remains stretched which can be clearly seen in step (3) of FIG. 1.

In step (4) it is shown that a bended gate-all-around MOSFET can be fabricated on the silicon nanowire.

FIG. 2 shows two SEM images of actual fabricated devices corresponding to steps (3) and (4) of FIG. 1.

The fabrication of nanowires is described in [11] for example. However, the method of oxidation-induced bending and hence strain build-up, could also be applied to silicon nanowires fabricated by other means.

The only requirements according to the shown embodiment are, that the wire is large enough to accommodate the consumption of silicon by oxidation and is fixed at both ends.

For top-down fabricated wires this is an advantage since it relaxes the requirement on scaling by lithographic means, and size reduction and bending is accomplished in the same step.

The silicon nanowire can be fabricated either on a bulk silicon wafer or a silicon-on-insulator substrate.

Various cross-sections of the silicon nanowire are possible. The inventors have demonstrated both, circular, triangular and pentagonal cross-sections.

In step 1 of FIG. 1 a silicon nanowire 1 is formed on a silicon substrate 4. Either end of the nanowire 1 is attached to a silicon plot, which will later form the source region 2 and the drain region 3.

In step 2 of FIG. 1 the silicon nanowire 1 is oxidized. This creates a silicon dioxide layer S. The created SiO2 occupy a larger volume than the corresponding Si. The greater volume of the oxide 5 compared to silicon 4 results in the deformation of the nanowire 1.

Hence the lattice is stretched to accommodate the pressure from the volume, since the nanowire is connected to the substrate 4 at both ends, this results in a bending of the wire 1.

In step 3 of FIG. 1 the sacrificial oxide 5 is removed in a BHF solution and the bending of the nanowire 1 persists.

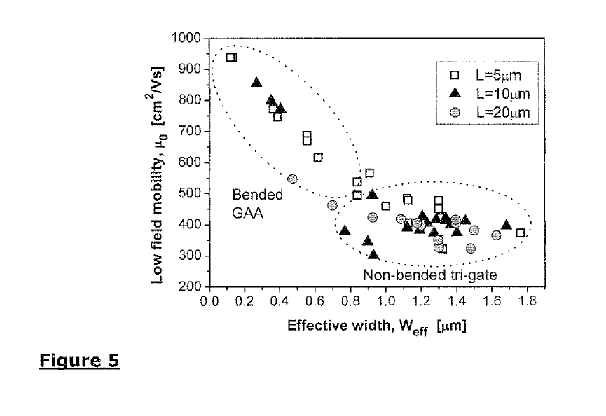

When the sacrificial oxide is removed in a BHF bath, the bending of the nanowire remains. Strain measurements carried out by micro-Raman spectroscopy, show a maximum of strain build up in the center of the wire, see FIG. 4 a.

In addition the strain and mobility enhancement increases with reducing wire width, see FIG. 4 b, in trend with observations in [2]

As shown in step 4 of FIG. 1, after nanowire bending and release, an isolation layer 6, a dielectric layer, is deposited on the wafer 4, planarized and etched back to reveal the bended silicon nanowire 1 and the source and drain plots 2 and 3.

In the present embodiment the isolating layer is a low-thermal oxide (LTO), but other insulators are possible as well.

This layer serves to isolate the gate from the substrate, in order to not turn on a parasitic substrate MOSFET in parallel with the nanowire MOSFET.

At Step 5 of FIG. 1 a gate stack is implemented by growing or depositing a gate dielectric 7 and a gate material 8, which may be for example poly-silicon or a metal. A self-aligned implantation will implant the gate 8 as well as the source 2 and drain 3 regions, including the parts of the nanowire 1 not overlapped by the gate.

One or several Gate-All-Around MOSFET can be fabricated along the wire by conventional silicon fabrication methods. A gate dielectric is grown or deposited and a gate material is deposited and patterned. A self-aligned implantation step can be carried out to dope the source, drain and gate regions, followed by an activation step.

Finally isolation and metallization steps (not shown) are carried out to contact and connect individual devices.

The bended gate-all around transistor depicted in FIG. 1 has a horizontal orientation (compared to the wafer surface) of the bended channel. A similar bending can be achieved for vertical gate-all around (or wrapped-gate) transistors that, in some cases, can offer better density of the integration and the possibility of 3D integrated circuits. FIG. 2 depicts the cross section of vertical bended GAA MOSFET.

Bending of a vertical wire will require both ends to be fixed during the oxidation process.

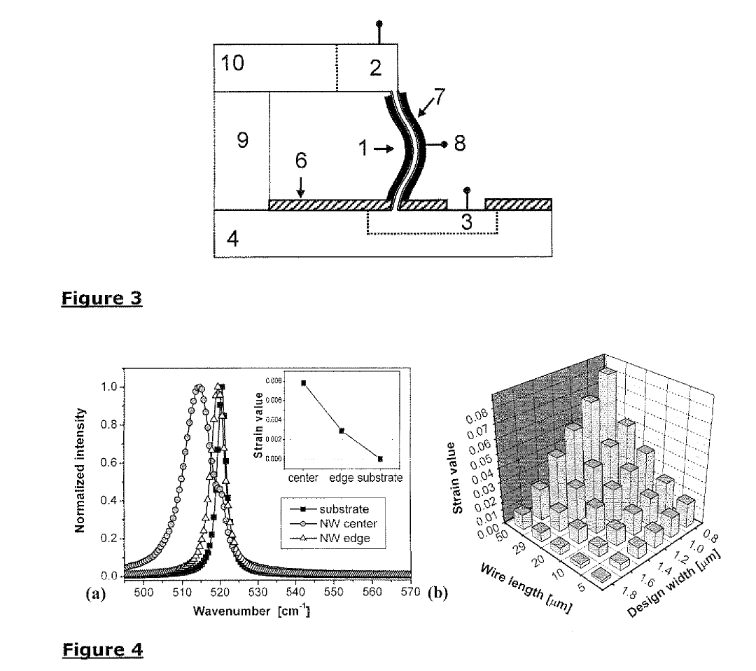

The extension of bended gate-all-around MOSFET principle to a vertical channel transistor is shown in FIG. 3.

The numbering (1)-(8) used in FIG. 1 are used accordingly in FIG. 3.

A vertical silicon nanowire 1 is formed. For bending both ends of the nanowire 1 should be fixed. According to the shown embodiment one end is fixed to substrate 4 in which the drain contact 3 is formed, whereas the other end of the wire 1 is fixed to a beam 10 in which the source contact 2 is formed.

Depending on the technology platform, a mechanical support might be required between the substrate 4 and the suspended beam 10.

FIG. 4 shows (a) the experimental variation of strain along a bended (suspended) nanowire. Inset shows that the strain value is maximum in the middle of the bended (suspended) nanowire.

In FIG. 4 (b) the strain dependence on nanowire length and on designed (lithographic) 2D width of the silicon rib is shown. It can be followed that smaller structures (size decreases with width and increasing length) present a greater amount of strain than larger wires.

The extracted low-field mobility for fabricated devices of differing length and circumference, W_{eff}, is shown in FIG. 5, where is depicted the Low field mobility as a function of effective width. The low field mobility is seen to increase with up to 100% for the bended MOSFETs compared to planar (non-strained) devices. Furthermore, the degree of enhancement increases with decreasing nanowire effective width.

It can be seen from FIG. 5 that the low filed mobility is constant for larger non-bended structures in accordance with classical theory. Whereas it increases with decreasing dimension, which corresponds to increasing strain.

### REFERENCES

[1]P. R. Chidambaram, C. Bowen, S. Chakravarthi, C. Machala and R. Wise, Fundamentals of Silicon Material Properties for Successful Exploitation of Strain Engineering in Modern CMOS Manufacturing, IEEE Trans. Electron Dev., Vol. 53, No. 5, pp. 944-964, 2006.
[2] R. He and P. Yang, Giant piezoresistance effect in silicon nanowires, Nature nanotechnology, Vol. 1, October, pp. 42-46, 2006.
[3] K. Uchida, R: Zednik, C.-H. Lu, H. Jagannathan, J. McVittie, P. McIntyre, and Y. Nishi, “Experimental study of biaxial and uniaxial strain effects on carrier mobility in bulk and ultrathin-body soi mosfets”, Tech. Digest. IEDM, (9.6.1):229-232, 2004.
[4] J. O. Chu and I. Khaled. U.S. Pat. No. 6,649,492. Strained Si based layer made by CHV CVD, and devices therein. Nov. 18, 2003.
[5] M. A. Shaheen. U.S. Pat. No. 7,157,379. Strained semiconductor structures, Jan. 2, 2007.
[6] B. Yu and R. van Bentum. U.S. Pat. No. 6,495,402. Semiconductor-on-insulator (SOI) device having source/drain silicon-germanium regions and method of manufacture, Dec. 17, 2002.
[7]M.-H. Lee, S. T. Chang, S. C. Lu and Chee-Wee Liu. U.S. Pat. No. 7,091,522. Strained silicon carbon alloy MOSFET structure and fabrication method thereof. Aug. 15, 2006.
[8]C.-H. Chang, W. Chang, C.-Y. Fu. U.S. Pat. No. 7,119,404. High performance strained channel MOSFETs by coupled stress effects. Oct. 1, 2006
[9] M. V. Ngo, P. R. Besser, M. R. Lin and H. Wang. U.S. Pat. No. 7,001,837. Semiconductor with tensile strained substrate and method of making the same. Feb. 21, 2006.
[10] Y. Ono, Y. Takahashi, K. Yamazaki, M. Nagase, H. Namatsu, K. Kurihara, K, Murase, “Fabrication method for IC-oriented Si single-electron transistors”, IEEE Transactions on Electron Devices Volume 47, Issue 1, pp. 147-153, 2000.
[11] D. Bouvet, K. E. Moselund and A. M. Ionescu.: Fabrication of Silicon nano wires and gate-all-around MOS devices, US 2007/0298551 A1, Dec. 27, 2007.
[12] K. E. Moselund, P. Dobrosz, S. Olsen, V. Pott, L. De Michielis, D. Tsamados, D. Bouvet, A. O'Neill, A. M. Ionescu, Bended Gate-All-Around Nanowire MOSET: a device with enhanced carrier mobility due to oxidation-induced tensile stress, Electron Devices Meeting, 2007. IEDM 2007. IEEE International, 10-12 Dec. 2007, pp. 191-194

1. A semiconductor device comprising a substrate; and
a nanowire in connection with the substrate at a drain and at a source region,
wherein the nanowire is bended to achieve enhanced mobility of charge carriers.

2. A semiconductor device according to claim 1, wherein the semiconductor device is a MOS transistor.

3. A semiconductor device according to claim 1, comprising single gates.

4. A semiconductor device according to claim 1, comprising multiple gates.

5. A semiconductor device according to claim 1, comprising a planar topography.

6. A semiconductor device according to claim 1, comprising a Gate-All-Around structure.

7. A semiconductor device according to claim 1, comprising a vertical structure compared to the wafer surface.

8. A method of manufacturing a semiconductor device comprising:
Providing a nanowire on a substrate connected to source and drain;
Oxidizing of the nanowire;
Removing of sacrificial oxide;
Depositing a dielectric layer on the substrate; and
Implementing a gate stack.

9. A method according to claim 8, wherein the nanowire is a silicon nanowire and the sacrificial oxide is removed in a BHF bath.

10. A method according to claim 8, wherein the deposited dielectric layer is planarized and etched back, to expose the nanowire and source and drain plots.

11. A method according to claim 8, wherein at least one Gate-all-around MOSFET is manufactured along a wire.

12. A method according to claim 8, wherein at least two Gate-all-around MOSFET is manufactured along a wire.

13. A method according to claim 7, wherein the gate stack is implemented by growing or depositing a gate dielectric.
